(19) United States
(12) Patent Application Publication
(10) Pub. No.: US 2025/0029819 A1
(43) Pub. Date: Jan. 23, 2025

(54) SPUTTERING APPARATUS AND METHOD FOR THIN FILM ELECTRODE DEPOSITION

(71) Applicant: Samsung Display Co., LTD., Yongin-si (KR)

(72) Inventors: You Jong LEE, Seoul (KR); Nam Wook KANG, Hwaseong-si (KR); Cheol Lae ROH, Seongnam-si (KR); Doo Seon YU, Cheonan-si (KR); Jeong Il LEE, Suwon-si (KR); Myung Soo HUH, Suwon-si (KR)

(21) Appl. No.: 18/910,046

(22) Filed: Oct. 9, 2024

Related U.S. Application Data
(62) Division of application No. 17/687,961, filed on Mar. 7, 2022.

(30) Foreign Application Priority Data
Sep. 13, 2021 (KR) 10-2021-0121654

(51) Int. Cl. H01J 37/34; C23C 14/34; C23C 14/35

(52) U.S. Cl. CPC H01J 37/3417; C23C 14/3485; C23C 14/352; H01J 37/342; H01J 37/3435; H01J 37/345; H01J 37/3467

(57) ABSTRACT

A sputtering apparatus includes: a first cylindrical target and a second cylindrical target, which are arranged in a first direction and parallel to each other; a first magnet disposed in the first cylindrical target; a second magnet disposed in the second cylindrical target; and a substrate holder spaced apart from the first and second cylindrical targets in a second direction which is perpendicular to the first direction, wherein each of a first angle formed by a first imaginary straight line from a center of the first magnet to a cylindrical axis of the first cylindrical target with a first perpendicular line and a second angle formed by a second imaginary straight line from a center to of the second magnet to a cylindrical axis of the second cylindrical target with a second perpendicular line is in a range of about 30 degrees to about 180 degrees.

This application is a divisional of U.S. patent application Ser. No. 17/687,961, filed on Mar. 7, 2022, which claims priority to Korean Patent Application No. 10-2021-0121654, filed on Sep. 13, 2021, and all the benefits accruing therefrom under 35 U.S.C. § 119, the content of which in its entirety is herein incorporated by reference.

### BACKGROUND

### (a) Field

The disclosure relates to a sputtering apparatus and method for forming a thin film electrode.

### (b) Description of the Related Art

A display device typically includes a plurality of pixels for displaying an image, and each of the pixels may include a light emitting element and one or more transistors, which are disposed on a substrate. The light emitting element may include a lower electrode and an upper electrode facing each other, and an organic layer disposed therebetween.

The display device may have a top emission structure that transmits light upwards of a substrate to secure a sufficient emission area. In a display device having the top emission structure, an upper electrode positioned above an organic layer may be a transparent or semi-transparent electrode such that light generated from the organic layer may pass therethrough to the outside. As the upper electrode, a thin conductive metal film is mainly used.

A reflective electrode that is thicker than the upper electrode is mainly used as the lower electrode, to have a resonance structure in which light that does not pass through the semi-transparent upper electrode is reflected back from the lower electrode toward the semi-transparent upper electrode.

In such a display device, various layers included in the display device may be formed by various deposition methods, such as sputtering, chemical vapor deposition, and thermal evaporation, for example. The thermal evaporation is a method of forming a film by vaporizing a material to be deposited in a high-temperature crucible. The sputtering is a method in which gas ions accelerated by electrical energy is allowed to collide with a target, which is a deposition material, in a vacuum state to deposit the emitted target particles on a deposition target such as a substrate.

### SUMMARY

Embodiments of the disclosure provide a sputtering apparatus and a sputtering method capable of preventing damage to a lower organic layer, increasing use efficiency of a deposition material, and easily forming a wide metal thin film electrode depending on enlargement of a display device when forming a thin metal thin film electrode directly on an organic layer of the display device.

An embodiment of the invention provides a sputtering apparatus including: a first cylindrical target and a second cylindrical target, which are arranged in a first direction and parallel to each other; a first magnet disposed in the first cylindrical target; a second magnet disposed in the second cylindrical target; a substrate holder spaced apart from the first and second cylindrical targets in a second direction which is perpendicular to the first direction, where a first angle formed by a first imaginary straight line from a center of the first magnet to a cylindrical axis of the first cylindrical target with a first perpendicular line is in a range of about 30 degrees to about 180 degrees, where the first perpendicular line is defined by an imaginary perpendicular line drawn from the cylindrical axis of the first cylindrical target to an upper surface of the substrate holder, and a second angle formed by a second imaginary straight line from a center of the second magnet to a cylindrical axis of the second cylindrical target with a second perpendicular line is in a range of about 30 degrees to about 180 degrees, wherein the second perpendicular line is defined by an imaginary perpendicular line drawn from the cylindrical axis of the second cylindrical target to the upper surface of the substrate holder; and a driver which moves the first and second cylindrical targets in the first direction while the substrate holder is fixed, or moves the substrate holder in the first direction while the first and second cylindrical targets are fixed.

In an embodiment, each of the first and second cylindrical targets may include a metal for forming a transmissive or semi-transmissive thin film electrode.

In an embodiment, during a sputtering process, each of the first and second cylindrical targets may rotate about the cylindrical axis thereof, and the first magnet and the second magnet may not swing.

In an embodiment, the first angle and the second angle may be the same as each other.

In an embodiment, the first magnet and the second magnet may be disposed in a way such that same poles thereof face each other.

In an embodiment, the first magnet and the second magnet may be disposed in a way such that opposite poles thereof face each other.

In an embodiment, the sputtering apparatus may further include a direct-current (“DC”) or alternating-current (“AC”) power supply connected between the first cylindrical target and the second cylindrical target.

In an embodiment, the power supply may use a bipolar DC method or a DC pulse method.

In an embodiment, the sputtering apparatus may further include an additional magnet disposed between the first cylindrical target and the second cylindrical target.

In an embodiment, the additional magnet may be disposed farther from the substrate holder than an imaginary straight line connecting the cylindrical axis of the first cylindrical target and the cylindrical axis of the second cylindrical target is.

In an embodiment, a ground voltage may be connected to the additional magnet.

An embodiment of the invention provides a sputtering method including: providing a substrate, on which an organic layer is deposited, in a chamber; injecting plasma generation gas into the chamber; generating plasma by applying a voltage to a first cylindrical target and a second cylindrical target positioned in the chamber and arranged in a first direction in parallel to each other; and forming a thin film electrode on the substrate by stacking particles of the first and second cylindrical targets on the organic layer, where a first angle formed by a first imaginary straight line from a center of a first magnet in the first cylindrical target to a cylindrical axis of the first cylindrical target with a first perpendicular line is in a range of about 30 degrees to about 180 degrees, where the first perpendicular line is defined by an imaginary perpendicular line drawn from the cylindrical axis of the first cylindrical target to an upper surface of the substrate holder, and a second angle formed by a second imaginary straight line from a center of a second magnet in the second cylindrical target to a cylindrical axis of the second cylindrical target with a second perpendicular line is in a range of about 30 degrees to about 180 degrees, wherein the second perpendicular line is defined by an imaginary perpendicular line drawn from the cylindrical axis of the second cylindrical target to the upper surface of the substrate holder.

In an embodiment, the forming the thin film electrode may include moving the first and second cylindrical targets in the first direction while the substrate holder is fixed, or moving the substrate holder in the first direction while the first and second cylindrical targets are fixed.

In an embodiment, each of the first and second cylindrical targets may include a metal for forming a transmissive or semi-transmissive thin film electrode.

In an embodiment, In the forming the thin film electrode, each of the first and second cylindrical targets may rotate about the cylindrical axis thereof, and the first magnet and the second magnet may not swing.

In an embodiment, the first angle and the second angle may be the same as each other.

In an embodiment, the first magnet and the second magnet may be disposed in a way such that same poles thereof face each other.

In an embodiment, the first magnet and the second magnet may be disposed in a way such that opposite poles thereof face each other.

In an embodiment, the sputtering method may further include applying a DC or AC power between the first cylindrical target and the second cylindrical target.

In an embodiment, an additional magnet may be disposed between the first cylindrical target and the second cylindrical target.

According to embodiments of the invention, it is possible to prevent damage to a lower organic layer, to increase use efficiency of a deposition material, and to easily form a wide metal thin film electrode for a large-sized display device when forming a thin metal thin film electrode directly on an organic layer of the display device.

### BRIEF DESCRIPTION OF THE DRAWINGS

FIG. 1 illustrates a cross-sectional structure of a display device according to an embodiment,

FIG. 2 illustrates a sputtering apparatus according to an embodiment,

FIG. 3 illustrates a sputtering apparatus according to an embodiment,

FIG. 4 illustrates a structure of a sputtering apparatus and magnetic field lines generated on an outside of the sputtering apparatus according an embodiment,

FIG. 5 illustrates a direction in which a substrate moves with respect to a sputtering apparatus according to an embodiment,

FIG. 6 illustrates a direction in which a sputtering apparatus moves with respect to a substrate according to an embodiment,

FIG. 7, FIG. 8, FIG. 9, FIG. 10, and FIG. 11 each illustrate an inner structure of a sputtering apparatus and magnetic field lines generated on an outside of the sputtering apparatus according an embodiment, and

FIG. 12 illustrates graphs illustrating characteristics of a light emitting element including a thin film electrode deposited using sputtering devices according to comparative examples and, a graph illustrating a light emitting element including a thin film electrode deposited using a sputtering device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

To clearly describe the invention, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the invention is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Further, in the specification, the phrase “in a plan view” means when an object portion is viewed from above, and the phrase “in a cross-sectional view” means when a cross-section taken by vertically cutting an object portion is viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

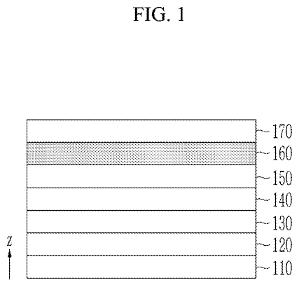

First, a structure of a display device according to an embodiment will now be described with reference to FIG. 1.

FIG. 1 illustrates a cross-sectional structure of a display device according to an embodiment.

An embodiment of a display device may include a substrate 110, a transistor array layer 120, an insulating layer 130, a lower electrode 140, an organic layer 150, an upper electrode 160, and a capping layer 170 which are sequentially positioned (or disposed) in a z direction, as show in FIG. 1. In an embodiment, at least one insulating layer, a conductive layer, etc. may be additionally positioned between adjacent layers of the layers shown in FIG. 1. When viewed on a plane to which the z direction is perpendicular, that is, when viewed from a plan view in the z direction, the display device may include a plurality of pixels capable of displaying an image.

In an embodiment, the substrate 110 may include an insulating material such as glass, plastic, or the like, and may have flexibility.

The transistor array layer 120 includes a semiconductor layer, an insulating layer, a conductive layer, and the like, and may include a plurality of transistors.

The insulating layer 130 may include an inorganic insulating material and/or an organic insulating material such as a silicon nitride (SiNx), a silicon oxide (SiOx), or a silicon oxynitride (SiON), and may include one or more insulating layers.

The lower electrode 140 is also referred to as a pixel electrode, and may be electrically connected to at least one transistor of the transistor array layer 120 to receive a data voltage. The lower electrode 140 may include a conductive material such as a metal including silver (Ag) or aluminum (Al), and may be semi-transmissive or reflective.

The organic layer 150 may include an emission layer, and may include at least one selected from an electron injection layer, a hole injection layer, an electron transport layer, and a hole transport layer. The organic layer 150 includes an organic material.

The upper electrode 160 is also referred to as a common electrode, and may transfer a common voltage across a plurality of pixels. In a display device having a top emission structure in which the display device displays an image in an upper direction of the substrate 110, i.e., in the z direction, the upper electrode 160 is transmissive or semi-transmissive such that light generated from the organic layer 150 may pass therethrough to the outside.

The upper electrode 160 may be positioned directly on and contact the organic layer 150.

The upper electrode 160 may include a conductive material such as a metal including silver (Ag) or aluminum (Al), and may be transmissive or semi-transmissive. In an embodiment where the upper electrode 160 includes a metal, the upper electrode 160 may be formed of or defined by a metal thin film electrode that is thinner than the lower electrode 140 for transmissive or semi-transmissive properties. In such an embodiment, a thickness of the upper electrode 160 in the z direction may be about 200 angstroms or less, but the invention is not limited thereto.

The lower electrode 140, the upper electrode 160, and the organic layer 150 therebetween together form a light emitting diode. One of the lower electrode 140 and the upper electrode 160 may function as a cathode of the light emitting diode, and the other of the lower electrode 140 and the upper electrode 160 may function as an anode.

The light emitting diode may have a resonance structure in which light that does not pass through the upper electrode 160 among the light emitted from the organic layer 150 is reflected back from the lower electrode 140 and passes through the upper electrode 160 or is reflected again.

The capping layer 170 may cover and protect the light emitting diode.

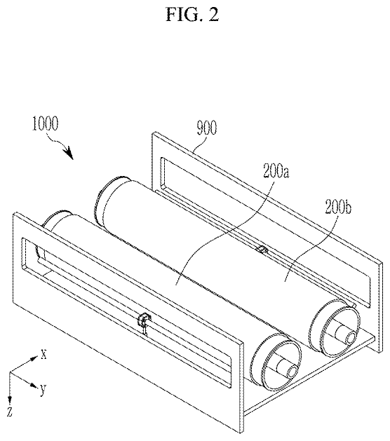

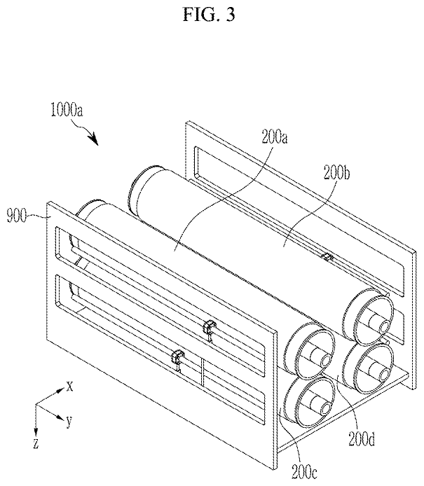

A sputtering apparatus for depositing the upper electrode 160 of a display device according to an embodiment will hereinafter be described with reference to FIG. 2 and FIG. 3.

FIG. 2 and FIG. 3 each illustrate a sputtering apparatus according to an embodiment.

Referring to FIG. 2, an embodiment of the sputtering apparatus 1000 includes two or more cylindrical targets 200a and 200b.

Each of the cylindrical targets 200a and 200b may include a material of a film to be deposited, and may be cylindrical around an axis of a cylinder. In an embodiment, the cylindrical targets 200a and 200b may each include a metal such as silver (Ag) or aluminum (Al) for forming a transparent or semi-transmissive thin film electrode like the upper electrode 160 described above.

The cylindrical targets 200a and 200b may constitute a cathode by receiving a cathode voltage.

A number of cylindrical targets 200a and 200b included in one sputtering apparatus 1000 may be an even number, but the invention is not limited thereto.

In an embodiment, as illustrated in FIG. 2, a pair of cylindrical targets 200a and 200b facing each other are arranged in an x direction and spaced apart in parallel to each other, and each of the cylindrical targets 200a and 200b may extend in the y direction.

In an embodiment, the sputtering apparatus 1000 may further include a support member 900 positioned around the cylindrical targets 200a and 200b. The support member 900 may support the cylindrical targets 200a and 200b, may receive a ground voltage, and may guide the target particles separated from the cylindrical targets 200a and 200b to mainly go out in an opposite direction to the z direction.

Each of the cylindrical targets 200a and 200b may rotate about a cylindrical axis during a sputtering process. Accordingly, a target material of the cylindrical targets 200a and 200b may be uniformly consumed, and use efficiency may be increased.

Referring to FIG. 3, the sputtering apparatus 1000a shown in FIG. 3 is mostly the same as the sputtering apparatus 1000 illustrated in FIG. 2 described above, except that four cylindrical targets 200a, 200b, 200c, and 200d are positioned. In embodiments of the invention, one sputtering apparatus 1000a may include an even number of cylindrical targets, such as six or eight.

In an embodiment where four or more cylindrical targets 200a, 200b, 200c, and 200d are positioned in one sputtering apparatus, different pairs of cylindrical targets 200a and 200b, and 200c and 200d, may be positioned adjacent to each other in the z-direction. Structures of the different pairs of the cylindrical targets 200a and 200b, and 200c and 200d, may be the same as each other. In such an embodiment, characteristics of the pair of cylindrical targets 200a and 200b to be described below may be equally applied to the other pair of cylindrical targets 200c and 200d.

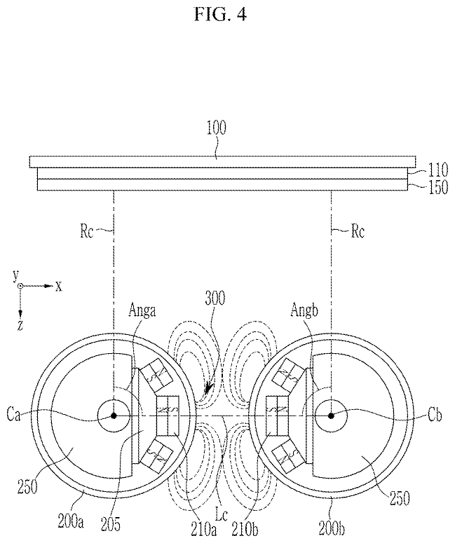

A specific structure of a cylindrical target included in the sputtering apparatus will be described with reference to FIG. 4 together with FIG. 1 to FIG. 3 described above.

FIG. 4 illustrates a structure of a sputtering apparatus and magnetic field lines generated on an outside of the sputtering apparatus according an embodiment.

Referring to FIG. 4, the organic layer 150, which may be the same as described above, may be already provided or formed on the substrate 110 on which a metal thin film is to be deposited (in the z direction). The substrate 110 may be fixed on a substrate holder 100.

The pair of cylindrical targets 200a and 200b are positioned in the x direction that is parallel to a surface of the substrate holder 100 or the substrate 110. Cylinder axes Ca and Cb of the respective cylindrical targets 200a and 200b may extend in the y direction.

A distance between the substrate holder 100 and the cylindrical targets 200a and 200b may vary depending on the process, but may be in a range of about 100 millimeters (mm) to about 500 mm, for example.

One or more magnets 210a and 210b for generating and maintaining plasma may be positioned inside each of the cylindrical targets 200a and 200b. FIG. 4 illustrates an embodiment in which three rows of magnets 210a and 210b are positioned inside each of the cylindrical target 200a and 200b, but a number of columns of the magnets 210a and 210b is not limited thereto, and may be four or more columns.

A magnet support 250 for supporting the magnets 210a and 210b, and a yoke plate 205 positioned between the magnet support 250 and the magnets 210a and 210b, may be further included inside each of the cylindrical targets 200a and 200b.

When an imaginary line drawn in the z direction from the cylindrical axes Ca and Cb of the respective cylindrical target 200a and 200b toward an upper surface of the substrate 110 or the substrate holder 100 is referred to as a perpendicular line Rc as shown in FIG. 4, angles formed by an imaginary straight line from a center of arrangement of the magnets 210a and 210b to the cylindrical axes Ca and Cb of the respective cylindrical targets 200a and 200b with the perpendicular line Rc are referred to as magnet angles Anga and Angb. Such magnet angles Anga and Angb may be in a range of about 30 degrees to about 180 degrees, and more specifically, may be in a range of about 30 degrees to about 150 degrees.

The magnet angles Anga and Angb of the two cylindrical targets 200a and 200b may be the same as or different from each other.

FIG. 4 illustrates an embodiment in which the center of the arrangement of the magnets 210a and 210b is positioned on an imaginary straight line Lc connecting the two cylindrical axes Ca and Cb of the two cylindrical targets 200a and 200b such that the magnet angles Anga and Angb may be about 90 degrees.

The magnet 210a inside the cylindrical target 200a and the magnet 210b inside the cylindrical target 200b facing each other may be disposed in a way such that same poles face each other, but the invention is not limited thereto.

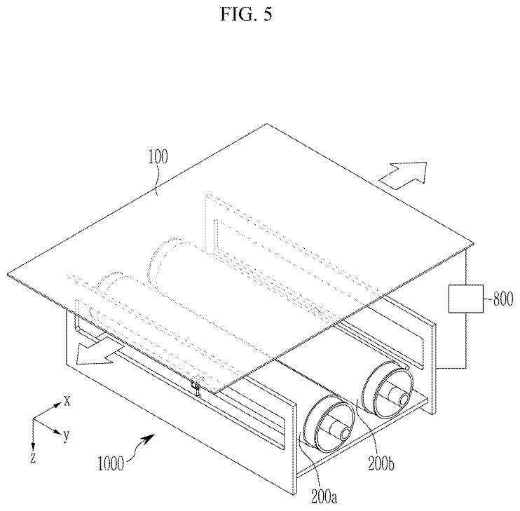

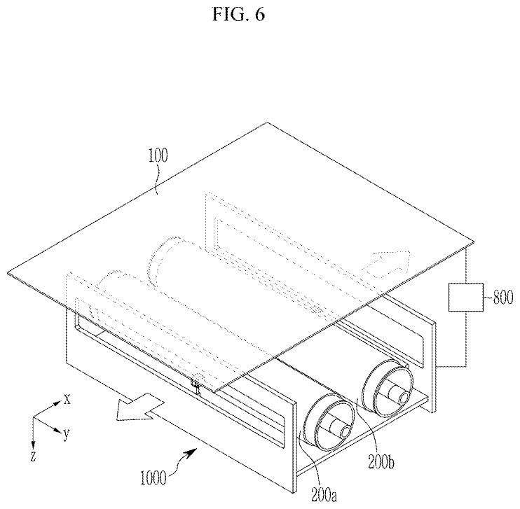

Next, a sputtering method according to an embodiment will be described with reference to FIG. 5 and FIG. 6 together with FIG. 2 to FIG. 4 described above.

A vacuum is made in a chamber, a gas for generating plasma, such as argon (Ar) gas, is injected into the chamber, and a voltage is applied to the cylindrical targets 200a and 200b under a constant pressure condition. In this case, a direct-current (“DC”) or alternating-current (“AC”) power supply for applying a cathode voltage to the cylindrical targets 200a and 200b and connecting an anode voltage or a ground voltage to a conductor positioned on an inner wall of the chamber or spaced from the cylindrical targets 200a and 200b may be used. Then, plasma is generated around an outer circumference of the cylindrical targets 200a and 200b. The cylindrical targets 200a and 200b may be sputtered while ions of the plasma accelerate and collide with the cylindrical targets 200a and 200b, which are cathodes, with high energy, and sputtered cylindrical target particles may be deposited on the organic layer 150 on the substrate 110.

In an embodiment, magnetic field lines 300 are formed near the outside of the cylindrical targets 200a and 200b in a space between the two cylindrical targets 200a and 200b by a configuration of the magnets 210a and 210b as described above, and plasma may be constrained in the space between the two cylindrical targets 200a and 200b by the magnetic field lines 300.

In such an embodiment, as described above, the magnet angles Anga and Angb may be in a range of about 30 degrees to about 180 degrees, such that numbers and kinetic energy of plasma ions directly incident on the organic layer 150 on the substrate 110, charged particles by the plasma, ion particles of the plasma generating gas reflected from the cylindrical targets 200a and 200b, sputtered target particles, etc. may be reduced by colliding with particles of the gas for plasma generation in the middle of movement. Accordingly, the organic molecules of the organic layer 150 having lower binding energy than kinetic energy of the plasma ions, the charged particles by the plasma, the ion particles of the gas for generating plasma reflected from the cylindrical targets 200a and 200b, the particles of the sputtered target, etc. may be effectively prevented from being damaged, or the molecular structure may be effectively prevented from being deformed during the sputtering process.

In an embodiment, as described above, the number and kinetic energy of the sputtered target particles reaching the organic layer 150 may be reduced to make it easy to control the process to protect the organic layer 150 and to form a thin film electrode to be deposited thereon, and thus the upper electrode 160 as a transmissive or semi-transmissive thin film electrode may be easily formed. The magnet angles Anga and Angb of the cylindrical targets 200a and 200b may be adjusted to be in a range of about 30 degrees to about 180 degrees based on a deposition rate of the upper electrode 160 and a degree of damage to the organic layer 150.

In such an embodiment, when the upper electrode 160 to be deposited is a transmissive or semi-transmissive thin film electrode containing a metal, probability of generating negative ions by the metal is very low, and thus acceleration of negative ions by the cylindrical targets 200a and 200b serving as cathodes and damage to the organic layer 150 due to collision with the organic layer 150 may be further reduced.

FIG. 5 illustrates a direction in which a substrate moves with respect to a sputtering apparatus according to an embodiment, and FIG. 6 illustrates a direction in which a sputtering apparatus moves relative to a substrate according to an embodiment.

During the process of an embodiment of the sputtering method described above, as illustrated in FIG. 5, the sputtering apparatus 1000 including the cylindrical targets 200a and 200b may perform a sputtering process while fixing a position and reciprocating or passing the substrate holder 100 on which the substrate 110 is mounted in the x direction. In an alternative embodiment, as illustrated in FIG. 6, the sputtering apparatus 1000 including the cylindrical targets 200a and 200b reciprocates or passes in the x direction while the substrate holder 100 is fixed, to perform the sputtering process.

In such embodiments, a driver 800 for moving the sputtering apparatus 1000 or the substrate holder 100 may be further included.

Alternatively, unlike as illustrated in FIG. 5 and FIG. 6, the substrate holder 100 may be positioned in a direction parallel to the y-direction or the z-direction, and the cylindrical targets 200a and 200b may also be positioned parallel to the substrate holder 100 or the substrate 110 corresponding thereto.

The embodiment illustrated in FIG. 4 and FIG. 5 may be equally applied to the sputtering apparatus 1000a of FIG. 3 described above.

In an embodiment, the sputtering apparatus 1000 or 1000a may increase use efficiency of the deposition material for forming the thin film electrode by using the cylindrical targets 200a and 200b and rotating the cylindrical targets 200a and 200b, and since sputtering may be performed by relatively reciprocating or passing the substrate holder 100 on which the substrate 110 is mounted and the sputtering apparatuses 1000 and 1000a, a wide metal thin film electrode for the wide upper electrode 160 to be included in a large sized display device may be uniformly and easily formed.

During an embodiment of the sputtering process, the magnets 210a and 210b may not swing. In such an embodiment, while sputtering is in progress, the magnet angles Anga and Angb of the magnets 210a and 210b of each of the cylindrical targets 200a and 200b may not change with time. Accordingly, damage to the organic layer 150 on which the thin film electrode is deposited may be further reduced.

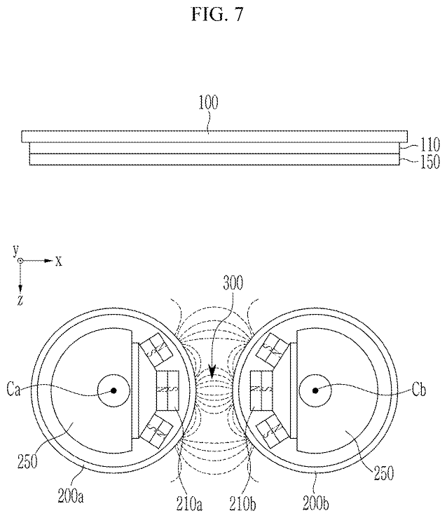

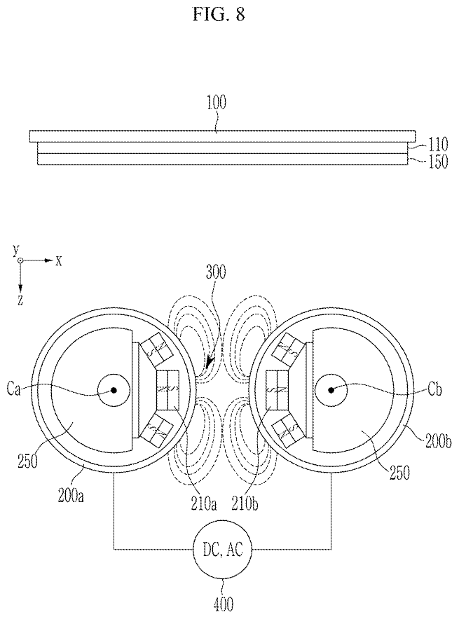

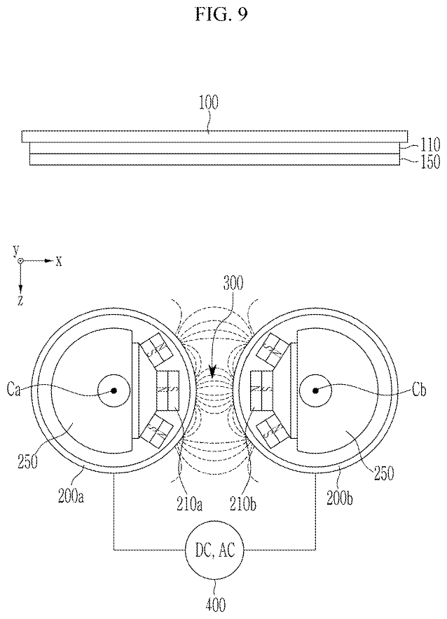

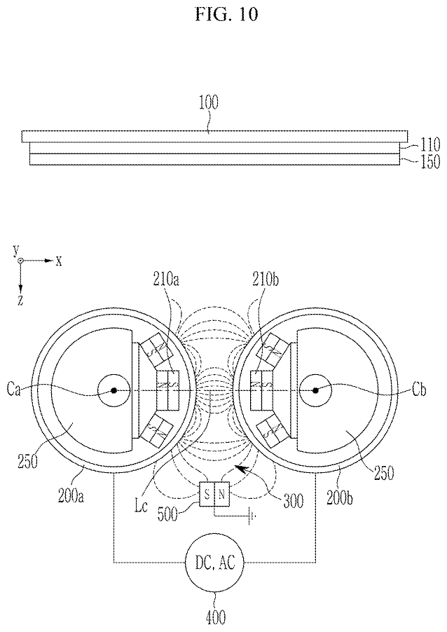

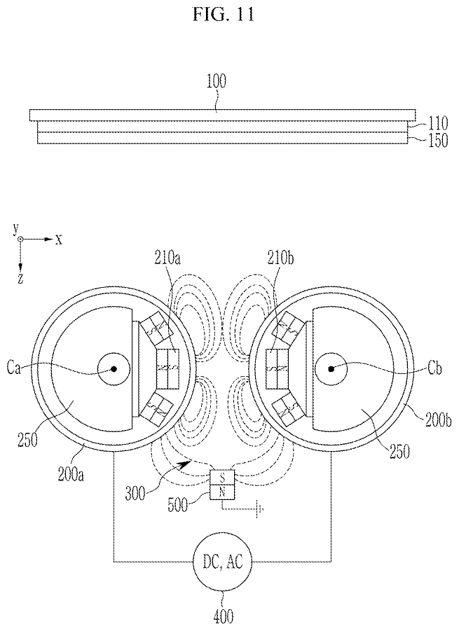

Next, a sputtering apparatus and a sputtering method according to an embodiment will be described with reference to FIG. 7 to FIG. 11 together with the previously described drawings.

FIG. 7, FIG. 8, FIG. 9, FIG. 10, and FIG. 11 each illustrate an inner structure of a sputtering apparatus and magnetic field lines generated on an outside of the sputtering apparatus according an embodiment.

Referring to FIG. 7, the sputtering apparatus and the sputtering method according to the embodiment are mostly the same as the sputtering apparatus and the sputtering method according to the embodiment illustrated in FIG. 4 to FIG. 6 described above, except that the magnet 210a inside the cylindrical target 200a and the magnet 210b inside the cylindrical target 200b facing each other may be arranged in a way such that opposite poles face each other.

In such an embodiment, the magnetic field lines 300 are more densely distributed between the two facing magnets 210a and 210b, and thus, charged particles may be more easily confined to a space between the two cylindrical targets 200a and 200b.

Referring to FIG. 8, the sputtering apparatus and the sputtering method according to the embodiment are mostly the same as the sputtering apparatus and the sputtering method according to the embodiment shown in FIG. 4 to FIG. 6 described above, except that a DC or AC power supply 400 may be further connected between the two facing cylindrical targets 200a and 200b. In such an embodiment, the power supply 400 may be a DC power supply device or an AC power supply device using a bipolar DC method, a DC pulse method, or the like, or may use a DC power supply and an AC power supply together.

Accordingly, in such an embodiment, plasma ions or charged particles are more effectively confined between the two opposing cylindrical targets 200a and 200b, thereby effectively preventing high energy collisions with the organic layer 150 on the substrate 110.

Referring to FIG. 9, the sputtering apparatus and the sputtering method according to the embodiment are mostly the same as the sputtering apparatus and the sputtering method according to the embodiment illustrated in FIG. 8 described above, except that the magnet 210a inside the cylindrical target 200a and the magnet 210b inside the cylindrical target 200b facing each other may be arranged in a way such that opposite poles face each other. In such an embodiment, as described above with reference to FIG. 7, the magnetic field lines 300 are more densely distributed between the two facing magnets 210a and 210b, and thus, charged particles may be more easily confined to a space between the two cylindrical targets 200a and 200b.

Referring to FIG. 10, the sputtering apparatus and the sputtering method according to the embodiment are mostly the same as the sputtering apparatus and the sputtering method according to any one of the embodiments illustrated in FIG. 4 to FIG. 9 described above, except that an additional magnet 500 may be further positioned between the two facing cylindrical targets 200a and 200b. The additional magnet 500 may be positioned at a far side from the substrate 110 with respect to the imaginary straight line Lc connecting the two cylindrical axes Ca and Cb among areas between the two cylindrical targets 200a and 200b.

The additional magnet 500 may be connected to a ground voltage or an anode voltage. The additional magnet 500 may be installed inside a bar- or rod-shaped conductive case. A ground voltage may be applied to the conductive case. The magnetic field lines 300 may be continuously formed between the additional magnet 500 and the magnets 210a and 210b inside the cylindrical targets 200a and 200b.

Accordingly, in such an embodiment, plasma ions or charged particles are further constrained by the magnetic field lines 300 formed by the additional magnet 500 to generate plasma in the space between the substrate 110 and the cylindrical targets 200a and 200b, thereby more effectively limiting the plasma ions or charged particles. Therefore, even when the magnet angles Anga and Angb are made smaller than 30 degrees such that the magnets 210a and 210b of the cylindrical targets 200a and 200b are slightly more toward the substrate 110, it is possible to improve a deposition rate of the thin film electrode while reducing damage to the organic layer 150.

Various voltages such as a cathode voltage in addition to a ground voltage and an anode voltage may be selectively applied to the additional magnet 500 or a conductive case including the additional magnet 500. Accordingly, ions, charged particles, and the like may be selectively guided toward the additional magnet 500 depending on polarity of the charge. Then, it is possible to more effectively reduce a damage factor of the organic layer 150 in a sputtering process by selecting a voltage applied to the additional magnet 500 depending on a charge mainly applied to particles affecting damage of the organic layer 150.

In an embodiment of FIG. 10, only the conductive case or a separate electrode may be positioned at the position of the additional magnet 500. In such an embodiment, one of a ground voltage, an anode voltage, and a cathode voltage may be applied to the conductive case or the separate electrode.

In an embodiment of FIG. 10, the magnet 210a inside the cylindrical target 200a and the magnet 210b inside the cylindrical target 200b facing each other are positioned in a way such that opposite poles face each other, but the invention is not limited thereto. in an alternative embodiment, as described above with reference to FIG. 4, the magnet 210a inside the cylindrical target 200a and the magnet 210b inside the cylindrical target 200b facing each other may be arranged in a way such that same poles face each other.

In an embodiment of FIG. 10, the DC or AC power supply 400 connected between the two cylindrical targets 200a and 200b facing each other may be omitted.

In an embodiment of FIG. 10, an N pole and an S pole of the additional magnet 500 are arranged to be adjacent in the x direction, but the invention is not limited thereto, and alternatively, the N pole and the S pole may be arranged to be adjacent in the z direction.

Referring to FIG. 11, the sputtering apparatus and the sputtering method according to the embodiment are mostly the same as those according to the embodiment illustrated in FIG. 10 described above, except that the magnet 210a inside the cylindrical target 200a and the magnet 210b inside the cylindrical target 200b facing each other are disposed in a way such that the same poles face each other is illustrated.

In an embodiment of FIG. 11, the DC or AC power supply 400 connected between the two cylindrical targets 200a and 200b facing each other may be omitted.

In an embodiment of FIG. 11, an N pole and an S pole of the additional magnet 500 are arranged to be adjacent in the z direction, but the invention is not limited thereto, and alternatively, the N pole and the S pole may be arranged to be adjacent in the x direction.

In various embodiments described above, one sputtering apparatus 1000 or 1000a includes an even number of cylindrical targets 200a, 200b, 200c, and 200d, but the invention is not limited thereto. In an alternative embodiment, one sputtering apparatus 1000 or 1000a may include an odd number of cylindrical targets. In embodiments of the sputtering apparatus of FIG. 4, FIG. 7, FIG. 8, FIG. 9, FIG. 10, or FIG. 11 described above, one cylindrical target 200a or 200b may be omitted, for example.

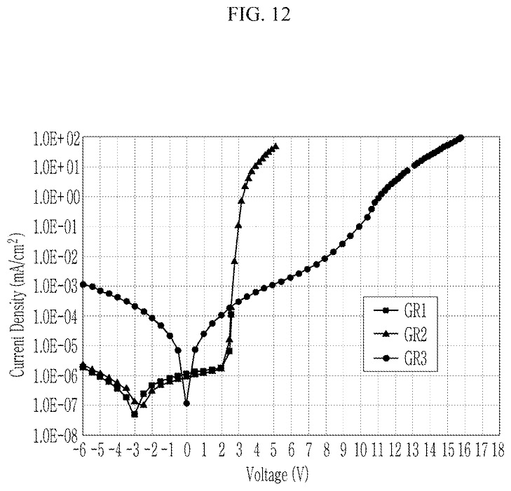

FIG. 12 illustrates graphs G1 and G3 illustrating characteristics of a light emitting element including a thin film electrode deposited using sputtering devices according to comparative examples, and a graph G2 illustrating a characteristic of a light emitting element including a thin film electrode deposited using a sputtering device according to an embodiment.

First, for the curve G3, unlike an embodiment of the invention, a magnet angle of a magnet of a cylindrical target is made smaller than 30 degrees so that the magnet faces a substrate, and it shows a current density characteristic with respect to a voltage of a light emitting diode including the upper electrode formed by sputtering and applying a DC voltage between the cylindrical target and a chamber.

Referring to the graph GR3, it can be seen that a leakage current of the light emitting diode increases at a reverse voltage, which is a negative voltage, so that a rectification characteristic of the light emitting diode is lost. Accordingly, dark spots may appear in an emission area of the pixels of the display device. This is due to damage to the organic layer 150 on the substrate 110 by sputtered target particles, plasma ions, and charged particles having high energy in the case of a comparative example.

In FIG. 12, the curve GR2 shows a current density characteristic with respect to the voltage of the light emitting diode including the upper electrode 160 formed by using the sputtering apparatus according to an embodiment of the invention.

Referring to the curve GR2, a leakage current of the light emitting diode decreases at the negative voltage, which is the reverse voltage, indicating a normal characteristic of the light emitting diode. The curve GR1 shows the current density characteristic with respect to the voltage of the light emitting diode formed by depositing the upper electrode 160 on the organic layer 150 using a thermal evaporation process, and it may be shown that it is almost identical to the curve GR2 according to an embodiment. Accordingly, it is possible to maintain a clean light emitting state without abnormality in the emission area of the pixel of the display device.

When the upper electrode 160 is formed by using the sputtering process using the sputtering apparatus according to an embodiment, compared to a case of using a thermal evaporation process, a period of filling a material may be considerably longer, and a material of a target is consumed only during the sputtering process, and thus a material loss and a process time may be minimized, and use efficiency of the deposition material may be increased. In a case of a conventional thermal deposition process, it is not easy to form the upper electrode of a large-sized display device. However, according to an embodiment of the invention, a wide metal thin film electrode may be easily formed for a large-sized display device, and density of the metal thin film compared to the thermal deposition process may be increased, so that lifespan and efficiency of the light emitting diode may be improved. In addition, in the thermal deposition process, it is desired to form a thick organic film of an encapsulation layer to cover a portion of the upper electrode that is not flat due to a splash phenomenon. According to an embodiment, the upper electrode is formed substantially flat, and thus the encapsulation layer may be made thin and a radius of curvature of the flexible display device may be further reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A sputtering method comprising:
providing a substrate, on which an organic layer is deposited, in a chamber;
injecting plasma generation gas into the chamber;
generating plasma by applying a voltage to a first cylindrical target and a second cylindrical target disposed in the chamber and arranged in a first direction in parallel to each other; and
forming a thin film electrode on the substrate by stacking particles of the first and second cylindrical targets on the organic layer,
wherein a first angle formed by a first imaginary straight line from a center of a first magnet in the first cylindrical target to a cylindrical axis of the first cylindrical target with a first perpendicular line is in a range of about 30 degrees to about 180 degrees, wherein the first perpendicular line is defined by an imaginary perpendicular line drawn from the cylindrical axis of the first cylindrical target to an upper surface of a substrate holder, and
a second angle formed by a second imaginary straight line from a center of a second magnet in the second cylindrical target to a cylindrical axis of the second cylindrical target with a second perpendicular line is in a range of about 30 degrees to about 180 degrees, wherein the second perpendicular line is defined by an imaginary perpendicular line drawn from the cylindrical axis of the second cylindrical target to the upper surface of the substrate holder.

2. The sputtering method of claim 1, wherein
the forming the thin film electrode includes moving the first and second cylindrical targets in the first direction while the substrate holder is fixed, or moving the substrate holder in the first direction while the first and second cylindrical targets are fixed.

3. The sputtering method of claim 1, wherein
each of the first and second cylindrical targets includes a metal for forming a transmissive or semi-transmissive thin film electrode.

4. The sputtering method of claim 1, wherein,
in the forming the thin film electrode,
each of the first and second cylindrical targets rotates about the cylindrical axis thereof, and
the first magnet and the second magnet do not swing.

5. The sputtering method of claim 1, wherein
the first angle and the second angle are the same as each other.

6. The sputtering method of claim 1, wherein
the first magnet and the second magnet are disposed in a way such that same poles thereof face each other.

7. The sputtering method of claim 1, wherein
the first magnet and the second magnet are disposed in a way such that opposite poles thereof face each other.

8. The sputtering method of claim 1, further comprising
applying an direct-current or alternating-current power between the first cylindrical target and the second cylindrical target.

9. The sputtering method of claim 1, wherein
an additional magnet is disposed between the first cylindrical target and the second cylindrical target.
